(19) United States
(12) Patent Application Publication
(10) Pub. No.: US 2023/0375936 A1
(43) Pub. Date: Nov. 23, 2023

(54) COMPOSITION FOR DEVELOPING AND METHOD OF FORMING PATTERN USING THE SAME

(71) Applicant: Samsung Electronics Co, Ltd., Suwon-si (KR)

(72) Inventors: Sangjin KIM, Suwon-si (KR); Chansik KIM, Suwon-si (KR); Geun Su LEE, Suwon-si (KR); Sungjae JUNG, Hwaseong-si (KR); Dokyeong KWON, Suwon-si (KR); Yigwon KIM, Suwon-si (KR); Hyunju SONG, Suwon-si (KR); Hyungju RYU, Suwon-si (KR); Tae Min CHOI, Suwon-si (KR); Keon HUH, Suwon-si (KR)

(73) Assignees: Geun Su Lee, Suwon-si (KR); Samsung Electronics Co, Ltd., Suwon-si (KR)

(21) Appl. No.: 18/153,568

(22) Filed: Jan. 12, 2023

(30) Foreign Application Priority Data
May 17, 2022 (KR) 10-2022-0060065

(51) Int. Cl. G03F 7/32; C08F 297/02

(52) U.S. Cl. CPC G03F 7/322; C08F 297/02

(57) ABSTRACT

A developing composition and a method of forming a pattern using the same are provided. According to embodiments of inventive concepts, the developing composition may include at least one repeating unit selected from a first repeating unit represented by Chemical Formula A1 a second repeating unit represented by Chemical Formula A2, or both the first repeating unit represented by Chemical Formula A1 and second repeating unit represented by Chemical Formula A2. The developing composition may further include a copolymer including a third repeating unit represented by Chemical Formula A3.

### CROSS-REFERENCE TO RELATED APPLICATIONS

This U.S. non-provisional patent application claims priority under 35 U.S.C. § 119 to Korean Patent Application No. 10-2022-0060065, filed on May 17, 2022, in the Korean Intellectual Property Office, the entire contents of which are hereby incorporated by reference.

### BACKGROUND

Inventive concepts relate to a developing composition, and more particularly, to a developing composition used for forming a resist pattern.

Photo-lithography may include an exposure process and a development process. Performing the exposure process may include irradiating light of a certain wavelength to a resist layer and inducing a change in a chemical structure of the resist layer. Performing the development process may include selectively removing an exposed portion or an unexposed portion by using a solubility difference between the exposed portion and the unexposed portion of the resist layer. Recently, as semiconductor devices have become highly integrated and miniaturized, components of semiconductor devices may require a fine pitch and a fine width. Accordingly, importance of the development process for forming a fine pattern favorably may increase.

### SUMMARY

An embodiment of inventive concepts provides a method of developing a pattern having improved pattern uniformity and improved pattern defect characteristics, and a developing composition used therein.

An embodiment of inventive concepts provides a developing composition having low surface tension and improved wetting characteristics.

Inventive concepts relate to a developing composition and/or a method of forming a pattern using the same.

According to an embodiment of inventive concepts, a developing composition may include a first repeating unit represented by Chemical Formula A1, a second repeating unit represented by Chemical Formula A2, or both the first repeating unit represented by Chemical Formula A1 and the second repeating unit represented by Chemical Formula A2. The developing composition may further include a copolymer including a third repeating unit represented by Chemical Formula A3.

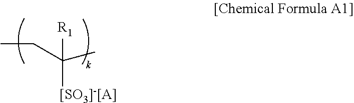

In Chemical Formula A1, “R₁” may be one of hydrogen, an alkyl group having 1 to 3 carbon atoms, and a halogenated alkyl group having 1 to 3 carbon atoms. “A” may be a substituted or unsubstituted ammonium salt, and “k” may be an integer selected from 1 to 5000.

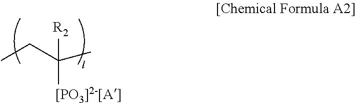

In Chemical Formula A2, “R₂” may be one of hydrogen, an alkyl group having 1 to 3 carbon atoms, and a halogenated alkyl group having 1 to 3 carbon atoms. “A” may be a substituted or unsubstituted ammonium salt, “l” may be an integer selected from 1 to 5000.

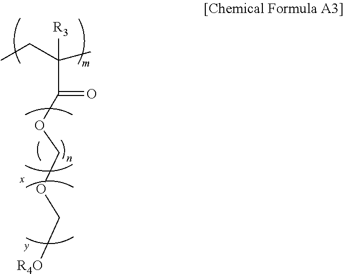

In Chemical Formula A3, “R₃” may be one of hydrogen, an alkyl group having 1 to 3 carbon atoms, and a halogenated alkyl group having 1 to 3 carbon atoms; “R₄” may be hydrogen, an alkyl group having 1 to 10 carbon atoms, or a hydroxyalkyl group having 1 to 10 carbon atoms; “m” may be an integer selected from 1 to 5000; “x” may be an integer selected from 1 to 100; “y” may be an integer selected from 0 to 100; “n” may be an integer selected from 1 to 5; and “o” may be an integer selected from 1 to 5.

According to an embodiment of inventive concepts, a developing composition may include a developer and a surfactant represented by Chemical Formula 1.

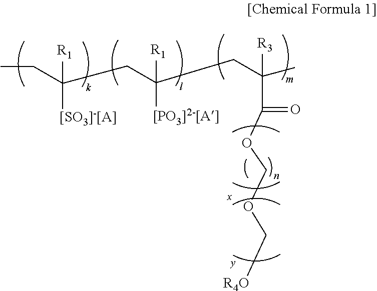

In Chemical Formula 1, each of “R₁”, “R₂”, and “R₃” independently may be one of hydrogen, an alkyl group having 1 to 3 carbon atoms, and a halogenated alkyl group having 1 to 3 carbon atoms; “R₄” may be hydrogen, an alkyl group having 1 to 10 carbon atoms, or a hydroxyalkyl group having 1 to 10 carbon atoms; each of “A” and “A′” independently may be a substituted or unsubstituted ammonium salt; “x” may be an integer selected from 1 to 100; “y” may be an integer selected from 0 to 100; “n” may be an integer selected from 1 to 5; “o” may be an integer selected from 1 to 5; “k”, “l”, and “m” each may be mole fractions of repeating units; each of “k” and “l” independently may be 0 to 0.3; “k+l” may be 0.05 to 0.3; “m” may be; and “k+l+m” may be 1.0.7 to 0.95

According to an embodiment of inventive concepts, a method of forming a pattern may include forming a resist layer on a substrate, performing an exposure process of irradiating light onto the resist layer, and performing a development process using the developing composition on the resist layer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view illustrating a resist pattern according to embodiments.

FIGS. 2 to 5 are views for illustrating a method of forming a lower pattern according to embodiments.

FIGS. 6 and 7 are views for illustrating a method of forming a lower pattern according to embodiments.

### DETAILED DESCRIPTION

Herein, an alkyl group may be a linear alkyl group, a branched alkyl group, or a cyclic alkyl group. The number of carbon atoms in the alkyl group is not particularly limited, but may be an alkyl group having 1 to 10 carbon atoms. Examples of the alkyl group include a methyl group, an ethyl group, an n-propyl group, an isopropyl group, an n-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3, 7-dimethyloctyl group, a cyclooctyl group, an n-nonyl group, and an n-decyl group, but are not limited thereto.

Herein, a hydroxyalkyl group may mean that a hydroxy group is substituted for hydrogen of an alkyl group. The number of carbon atoms in the hydroxyalkyl group is not particularly limited, but may be 1 or more and 10 or less.

Herein, the number of carbon atoms of the alkoxy group is not particularly limited, but may be 1 or more and 10 or less. The alkoxy group may include an alkyl alkoxy group and an aryl alkoxy group. The alcohol of the alkoxy group may include a primary alcohol, a secondary alcohol, and a tertiary alcohol.

As used herein, “substituted or unsubstituted” means substituted or unsubstituted with at least one substituent selected from the group consisting of a hydrogen atom, a deuterium atom, a halogen atom, a hydroxyl group, an alkoxy group, a halogenated alkyl group, a nitro group, an amino group, an alkyl group, an alkenyl group, an aryl group, and a heterocyclic group. In addition, each of the substituents described above may be substituted or unsubstituted. For example, a hydroxy alkyl group may be interpreted as an alkyl group.

Unless otherwise defined in chemical formulas of the present specification, when a chemical bond is not drawn at a position where a chemical bond is to be drawn, it may mean that a hydrogen atom is bonded to the position.

Hereinafter, a composition according to an embodiment of inventive concepts will be described.

According to an embodiment of inventive concepts, the composition may be a developing composition. The developing composition may be used for forming a pattern and/or for manufacturing a semiconductor device. For example, the developing composition may be used in a patterning process for manufacturing the semiconductor device. In detail, the developing composition may be used for removing a resist layer in a development process.

According to embodiments, the developing composition may include a developer and a copolymer. The copolymer may function as a surfactant. The copolymer may be a surfactant copolymer. The copolymer may include at least one of a sulfonate and a phosphate. For example, the copolymer may include at least one repeating unit of a first repeating unit, a second repeating unit, and a third repeating unit. The first repeating unit may include a sulfonate and may be represented by Chemical Formula A1 below. The second repeating unit may include a phosphate and may be represented by Chemical Formula A2 below. The third repeating unit may be combined with the first repeating unit or the second repeating unit. The third repeating unit may be different from the first and second repeating units. The third repeating unit may be represented by Chemical Formula A3 below.

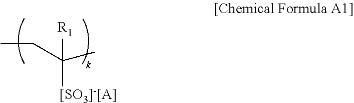

In Chemical Formula A1, “R₁” may be one of hydrogen, an alkyl group having 1 to 3 carbon atoms, and a halogenated alkyl group having 1 to 3 carbon atoms, “A” may be a substituted or unsubstituted ammonium salt, and “k” may be an integer selected from 1 to 5000.

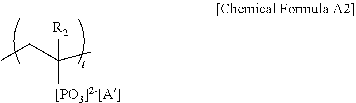

In Chemical Formula A2, “R₂” may be one of hydrogen, an alkyl group having 1 to 3 carbon atoms, and a halogenated alkyl group having 1 to 3 carbon atoms, “A′” may be a substituted or unsubstituted ammonium salt, and “l” may be an integer selected from 1 to 5000.

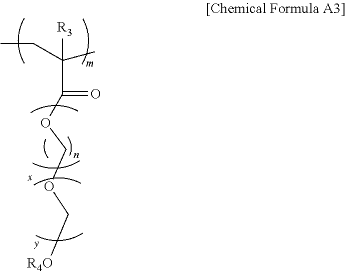

In Chemical Formula A3, “R₃” is one of hydrogen, an alkyl group having 1 to 3 carbon atoms, and a halogenated alkyl group having 1 to 3 carbon atoms, and “R₄” is hydrogen, an alkyl group having 1 to 10 carbon atoms, or a hydroxyalkyl group having 1 to 10 carbon atoms, “m” is an integer selected from 1 to 5000, “x” is an integer selected from 1 to 100, “y” is an integer selected from 0 to 100, “n” is an integer selected from 1 to 5, and “o” is an integer selected from 1 to 5.

The copolymer may include the third repeating unit represented by Chemical Formula A3 and may be flexible.

According to embodiments, the copolymer may be represented by Chemical Formula 1.

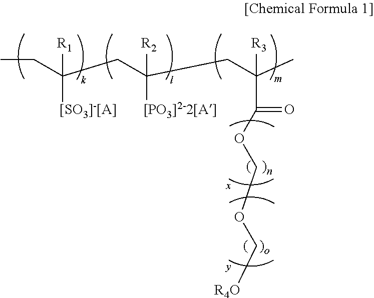

In Chemical Formula 1, each of “R₁”, “R₂”, and “R₃” is independently one of hydrogen, an alkyl group having 1 to 3 carbon atoms, and a halogenated alkyl group having 1 to 3 carbon atoms, “R₄” is hydrogen, an alkyl group having 1 to 10 carbon atoms, or a hydroxyalkyl group having 1 to 10 carbon atoms, each of “A” and “A′” is independently a substituted or unsubstituted ammonium salt, “x” is an integer selected from 1 to 100, “y” is an integer selected from 0 to 100, “n” is 1 to 5, “o” is an integer selected from 1 to 5, “k”, “l”, and “m” are each a mole fraction of a repeating unit, each of “k” and “l” is independently 0 to 0.3, “k+l” is 0.05 to 0.3, “m” is 0.7 to 0.95, and “k+l+m” is 1.

The resist layer may form a resist pattern using the developing composition. The resist pattern may be a photoresist pattern. Forming the photoresist pattern may include removing a first portion of the photoresist layer. The photoresist layer may be hydrophobic.

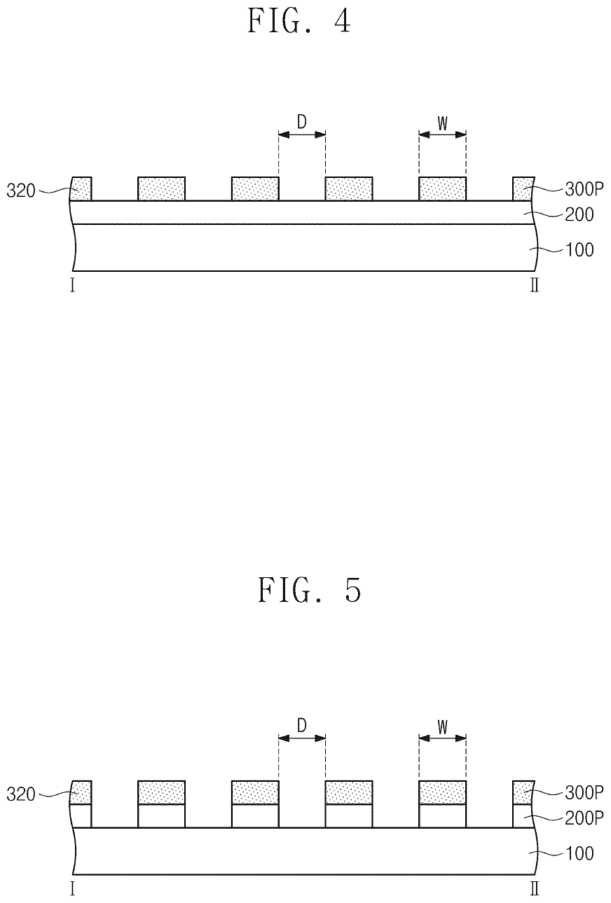

The copolymer may be a surfactant. [SO₃]⁻[A] in Chemical Formula A1 and [PO₃]²⁻2[A′] in Chemical Formula A2 may be hydrophilic. Accordingly, the copolymer may have high solubility in a solvent (e.g., deionized water). The third repeating unit represented by Chemical Formula A3 may be hydrophobic. The copolymer may have a hydrophobic portion, and thus the developing composition may have a relatively low surface tension. Accordingly, wetting characteristics of the developing composition with respect to the resist layer may be improved. When the developing composition includes the copolymer, an interaction between the developing composition (e.g., alkaline developer) and the photoresist layer may become more uniform. The development process using the developing composition will be described in more detail with reference to FIG. 4.

According to one embodiment, “R₁”, “R₂”, or “R₃” in Chemical Formula A1, Chemical Formula A2, Chemical Formula A3, and Chemical Formula 1 may be a perhalogenated alkyl group having 1 to 3 carbon atoms.

According to an embodiment, “R₁”, “R₂”, or “R₃” in Chemical Formula A1, Chemical Formula A2, Chemical Formula A3, and Chemical Formula 1 may be a fluorinated alkyl group having 1 to 3 carbon atoms.

According to an embodiment, “R₁”, “R₂”, or “R₃” in Chemical Formula A1, Chemical Formula A2, Chemical Formula A3, and Chemical Formula 1 may be a perfluorinated alkyl group having 1 to 3 carbon atoms.

According to an embodiment, “R₁”, “R₂”, or “R₃” of in Chemical Formula A1, Chemical Formula A2, Chemical Formula A3, and Chemical Formula 1 may be a methyl group or a trifluoromethyl group.

According to an embodiment, in Chemical Formula 1, the number of repeating units represented by “k” is 0 to 5000, the number of repeating units represented by “l” is 0 to 5000, and the number of repeating units represented by “m” is 1 to 5000. In this case, the sum of the number of repeating units represented by “k” and the number of repeating units represented by “l” is 1 to 10000.

According to an embodiment, in in Chemical Formula A1, Chemical Formula A2, and Chemical Formula 1, when “A” and/or “A′” is a substituted ammonium salt, each of “A” and/or “A′” may be an ammonium salt substituted with a hydroxy group, an alkyl group having 1 to 10 carbon atoms, an alkoxy alkyl group having 2 to 10 carbon atoms, a hydroxyalkyl group having 1 to 10 carbon atoms, or an aryl group having 6 to 12 carbon atoms, independently. Here, the aryl group may be substituted or unsubstituted.

In Chemical Formula A1 and Chemical Formula 1, “A” may be represented by Chemical Formula 2 below.

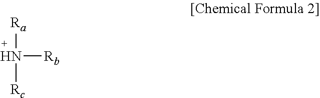

In Chemical Formula 2, each of “Rₐ”, “R_{b}”, and “R_{c}” is independently hydrogen, a hydroxy group, an alkoxy group having 1 to 10 carbon atoms, an alkyl group having 1 to 10 carbon atoms, an alkoxy alkyl group having 2 to 10 carbon atoms, a hydroxyalkyl group having 1 to 10 carbon atoms, or a substituted or unsubstituted aryl group having 6 to 12 carbon atoms.

In Chemical Formula A2 and Chemical Formula 1, “A′” may be represented by Chemical Formula 3 below.

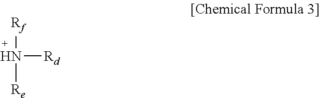

In Chemical Formula 3, each of “R_{d}”, “Rₑ”, and “R_{f}” is independently hydrogen, a hydroxy group, an alkoxy group having 1 to 10 carbon atoms, an alkyl group having 1 to 10 carbon atoms, an alkoxy alkyl group having 2 to 10 carbon atoms, a hydroxyalkyl group having 1 to 10 carbon atoms, or a substituted or unsubstituted aryl group having 6 to 12 carbon atoms.

According to an embodiment, in Chemical Formula 2, at least one of “Rₐ”, “R_{b}”, and “R_{c}” may include a hydroxyalkyl group. The hydroxy group alkyl group may include, for example, a hydroxy ethyl group, but is not limited thereto.

In Chemical Formula 2 and Chemical Formula 3, the alkyl group may be a linear or branched alkyl group.

For example, in Chemical Formula 2 and Chemical Formula 3, the alkyl group having 1 to 10 carbon atoms may include a methyl group, an ethyl group, a propyl group, a butyl group or an isopropyl group, and a tert-butyl group.

For example, in Chemical Formula 2 and Chemical Formula 3, the alkoxy alkyl group having 2 to 10 carbon atoms may include a 1-methoxymethyl group, a 2-methoxyethyl group, a 1-methoxyethyl group, a 3-methoxypropyl group, a 1-methoxypropyl group, a 2-methoxypropyl group, a 1-ethoxy methyl group, a 2-ethoxy ethyl group, a 1-ethoxy ethyl group, a 3-ethoxy propyl group, a 2-ethoxy propyl group, and a 1-ethoxy propyl group.

For example, in Chemical Formula 2 and Chemical Formula 3, the hydroxyalkyl group having 1 to 10 carbon atoms may include a 1-hydroxymethyl group, a 2-hydroxyethyl group, a 1-hydroxyethyl group, a 3-hydroxypropyl group, a 2-hydroxy propyl group, a 1-hydroxy propyl group, a 1-methyl-1-hydroxyethyl group, and a 1-methyl-2-hydroxy ethyl group.

For example, in Chemical Formula 2 and Chemical Formula 3, the substituted or unsubstituted aryl group having 6 to 12 carbon atoms may include a hydroxyalkyl group, a phenyl group, a tolyl group, a xylyl group, and a naphthyl group.

In Chemical Formula 1, “A” and “A′” may be the same ammonium salt. In this case, Chemical Formula 2 may be the same as Chemical Formula 3.

In Chemical Formula 1, “A” and “A′” may be different ammonium salts.

In Chemical Formula 1, each of “A” and “A′” may independently be one selected from Compound group Z.

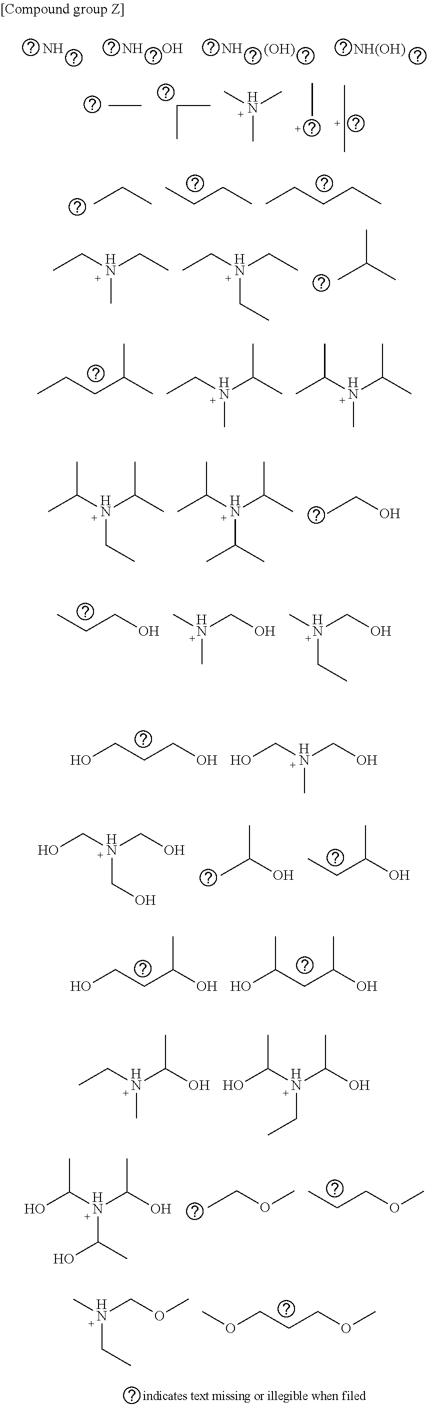

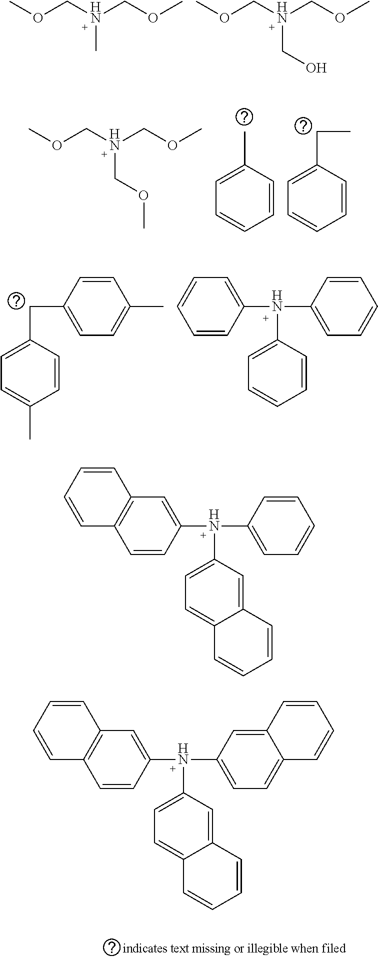

According to an embodiment, in Chemical Formula 1, “x” may be an integer selected from 1 to 10, “y” may be an integer selected from 0 to 10, “n” may be 2 or 3, and “o” may be 1, 2, or 3. However, “x”, “y”. “n”, and “o” are not limited thereto.

According to embodiments, a weight average molecular weight (Mw) of the copolymer may be 300 g/mol to 50,000 g/mol. For example, the weight average molecular weight (Mw) of the copolymer may be 500 g/mol to 10,000 g/mol. The weight average molecular weight (Mw) of the copolymer may mean a weight average molecular weight of the material represented by Chemical Formula 1, but is not limited thereto.

The copolymer may have a weight average molecular weight of 300 g/mol to 50,000 g/mol, and thus the copolymer may have high solubility in a developing composition (e.g., a mixture of a developer and a solvent). When the weight average molecular weight of the copolymer is greater than 50,000 g/mol, the copolymer may have low solubility in the developing composition. Accordingly, it may be difficult to prepare the developing composition or storage stability of the developing composition may be poor. When the weight average molecular weight of the copolymer is less than 300 g/mol, wetting characteristics of the developing composition with respect to the resist layer may be deteriorated. Accordingly, it may be difficult for the resist layer to be favorably patterned.

According to embodiments, the copolymer may have a weight average molecular weight (Mw) of 300 g/mol to 50,000 g/mol, and thus the copolymer may be favorably dissolved in the developing composition. The developing composition may be stored stably for a long time. In addition, when the developing composition according to the embodiments is used, the resist layer may be favorably patterned. During the development process, deformation of the resist pattern may be limited and/or prevented.

The copolymer may have 0.001 to 1 part by weight.

The developer may be an alkali-based developer. The alkali-based developer may be an aqueous alkali-based developer. The developer may include an alkyl ammonium hydroxide. In detail, the developer may include tetraalkylammonium hydroxide having 4 to 20 carbon atoms. For example, the developer may include tetramethylammonium hydroxide (TMAH). As another example, the developer may include ethyltrimethylammonium hydroxide (ETMAH), tetraethylammonium hydroxide (TEAH), tetrapropylammonium hydroxide (TPAH), and/or tetrabutylammonium hydroxide (TBAH). The developer may have 0.5 to 3 parts by weight. The developer may be a positive tone developer, but is not limited thereto.

The solvent may include, for example, water such as deionized water. The solvent may have from 92 to 99.499 parts by weight.

The developing composition may further include a defoamer. The defoamer may be an alcohol-based. The defoamer may include an aliphatic alkyl alcohol compound having 1 to 10 carbon atoms and a cyclic aliphatic alkyl alcohol compound having 1 to 10 carbon atoms. For example, the defoamer may include methanol, ethanol, ethanol, n-propanol, isopropanol, n-butanol, 2-butanol, tert-butanol, n-pentanol, 2-pentanol, isoamyl alcohol, cyclopropanol, cyclobutanol, cyclopentanol, and/or cyclohexanol. The defoamer may have 0 to 3 parts by weight. For example, the defoamer may have 0.001 to 3 parts by weight. The developing composition may further include the defoamer, and thus generation of air bubbles in the development process using the developing composition may be limited and/or suppressed or the generated air bubbles may be removed.

The developing composition may further include a pH regulator. The pH regulator may include a hydroxyl amine or an alkyl amine having 1 to 15 carbon atoms. The alkyl amine may be a primary alkyl amine, a secondary alkyl amine, or a tertiary alkyl amine. The alkyl group may include a hydroxy group alkyl or unsubstituted alkyl. For example, the alkyl amine is trimethylamine, triethylamine, triethanolamine, tri-n-butylamine, monoethanolamine, and/or diethanolamine.

As another example, the developing composition may include an acid. For example, the developing composition may include acetic acid, propionic acid, oleic acid, stearic acid, salicylic acid, benzoic acid, formic acid, malonic acid, fumaric acid, citric acid, hydrochloric acid, sulfuric acid, nitric acid, sulfonic acid, tosylic acid, and/or trifluoromethanesulfonic acid.

When the developing composition may include hydroxyl amine, alkyl amine, or acid, metallic impurities may not remain on the photoresist pattern after the development process. As another example, the pH regulator may include sodium hydroxide, potassium hydroxide, barium hydroxide, and/or calcium hydroxide.

The pH regulator may have 0 to 1 parts by weight. For example, the pH regulator may have 0.001 to 3 parts by weight.

Hereinafter, a method for preparing a copolymer according to embodiments will be described.

Forming the copolymer may include reacting at least one of a sulfonic acid-based monomer and a phosphoric acid-based monomer with an amine compound represented by Chemical Formula C to form a first salt, and polymerizing the first salt with an acrylic monomer. The sulfonic acid-based monomer may be represented by Chemical Formula B1, the phosphoric acid-based monomer may be represented by Chemical Formula B2, and the amine compound may be represented by Chemical Formula C.

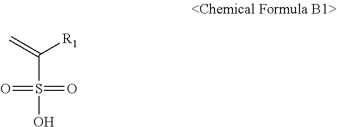

In Chemical Formula B1, “R₁” is as defined in Chemical Formula A1.

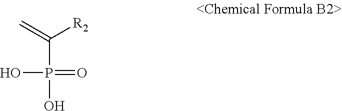

In Chemical Formula B2, “R₂” is as defined in Chemical Formula A1.

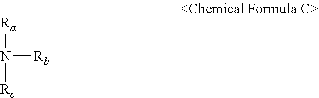

In Chemical Formula C, “Rₐ”, “R_{b}”, and “R_{c}” are as defined in Chemical Formula 2.

A reaction of the sulfonic acid-based monomer with the amine compound may proceed as shown in Scheme 1.

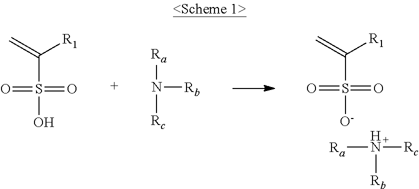

In Scheme 1, “R₁” is as defined in Chemical Formula A1, and each of “Rₐ”, “R_{b}”, and “R_{c}” may be independently hydrogen, a hydroxyl group, an alkoxy group having 1 to 10 carbon atoms, an alkyl group having 1 to 10 carbon atoms, an alkoxyalkyl group having 2 to 10 carbon atoms, a hydroxyalkyl group having 1 to 10 carbon atoms, or a substituted or unsubstituted aryl group having 6 to 12 carbon atoms.

A reaction between the phosphoric acid-based monomer and the amine compound may proceed as shown in Scheme 2.

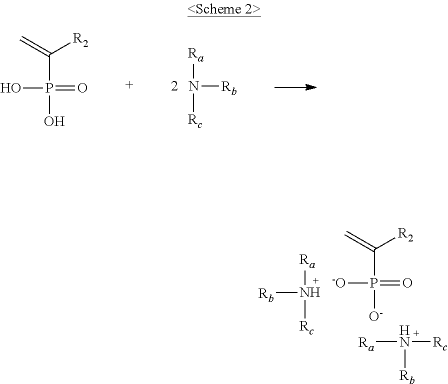

In Scheme 1, “R₂” is as defined in Chemical Formula A2, and “Rₐ”, “R_{b}”, and “R_{c}” are as defined in Scheme 1.

A reaction represented by Scheme 1 and Scheme 2 may be performed at a temperature of 10° C. to 15° C. for 4 to 24 hours. In Scheme 1 and Scheme 2, a first reaction solvent may be used as a solvent. The first reaction solvent may include tetrahydrofuran (THF) and/or an alcohol-based solvent. The alcohol-based solvent may include ethanol, n-propanol, isopropanol, n-butanol, 2-butanol, tert-butanol, n-pentanol, 2-pentanol, isoamyl alcohol, and/or propylene glycol monomethyl ether. When the first reaction solvent further includes an alcohol-based solvent, solubility of a reactant in the first reaction solvent may be adjusted.

The first reaction solvent may be 5 parts by weight to 70 parts by weight of the reactants. For example, the first reaction solvent may be 20 parts by weight to 60 parts by weight of the reactants. In this case, the reactants may include at least one of a monomer represented by Chemical Formula B1 and a monomer represented by Chemical Formula B2, and a monomer represented by Chemical Formula C.

The reaction represented by Scheme 1 and Scheme 2 may be performed to form the first salt. The first salt is reacted with a monomer represented by Chemical Formula B3 to form a copolymer. The monomer represented by Chemical Formula B3 may include an acrylate monomer.

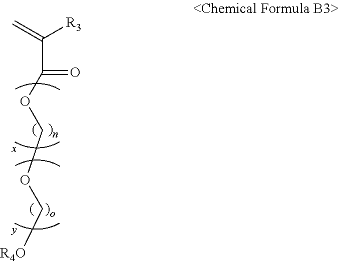

In Chemical Formula B3, “R₃”, “R₄”, “x”, and “y” are as defined in Chemical Formula A3.

The reaction of the first salt with the monomer represented by Chemical Formula B3 may proceed as shown in Scheme 3 below.

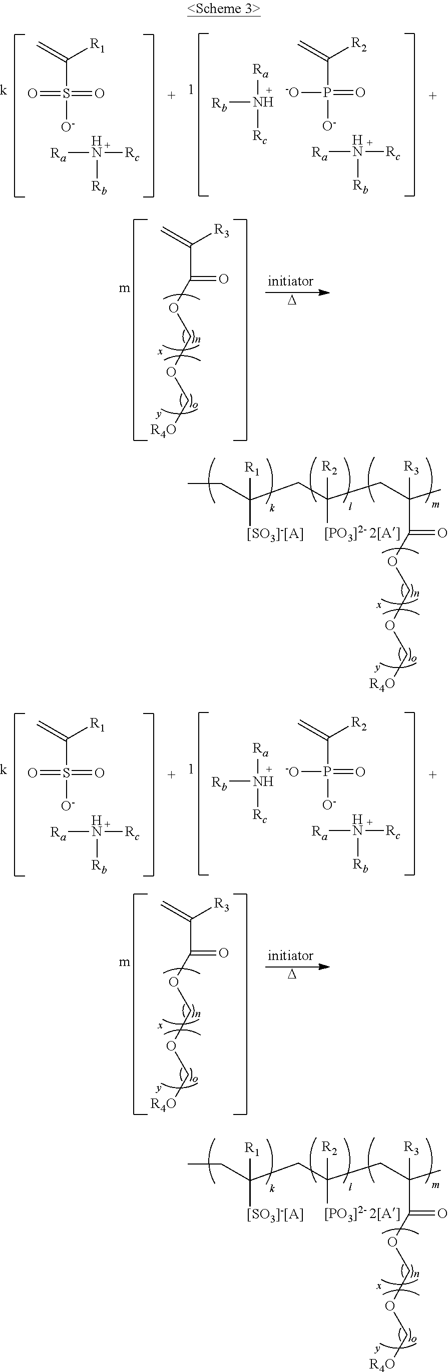

In Scheme 3, “R₁”, “Rn”, “R₃”, “R” n “k”, “l”, “n”, “x”, and “y” are each as defined in Chemical Formula 1, and “Rₐ”, “R_{b}”, and “R” are each as defined in Chemical Formula 2.

In Scheme 3, each of “k” and “l” is an integer independently selected from 0 to 5000, “k+m” is 1 or more, and “in” is independently an integer selected from 1 to 5000.

Scheme 3 may be a radical polymerization reaction. Scheme 3 may be carried out at a temperature of 50° C. to 150° C. for 1 hour to 72 hours. In Scheme 3, a second reaction solvent may be further used as a solvent. The second reaction solvent may include tetrahydrofuran (THF) and/or an alcohol-based solvent. The alcohol-based solvent may be substantially the same as described above for the example of the first reaction solvent. In Scheme 3, reactants may have high solubility in the second reaction solvent. The second reaction solvent may be 10 to 70 parts by weight of the reactants of Scheme 3. For example, the second reaction solvent may be 30 to 60 parts by weight of the reactants of Scheme 3.

Scheme 3 may be carried out using an initiator. The initiator may be a polymerization initiator. The initiator may include an azo compound, a hydroperoxide compound, a peroxyester compound and/or a diacylperoxide. The azo compound may include, for example, 2,2′-azobis(2-methylbutyronitrile), 2,2′-azobisisobutyronitrile (AIBN) and 2,2′-azobis(2-cyanopentane). The hydroperoxide compound may include, for example, cumene, t-butyl- and t-amyl-hydroperoxide. The peroxyester compound may include, for example, t-butylperbenzoate, and/or dit-butylperoxyphthalate. The diacyl peroxide may include, for example, benzoyl peroxide, and lauroyl peroxide. However, the type of the initiator may not be limited thereto.

Hereinafter, a method of forming a pattern and a method of manufacturing a semiconductor device using a composition according to embodiments will be described.

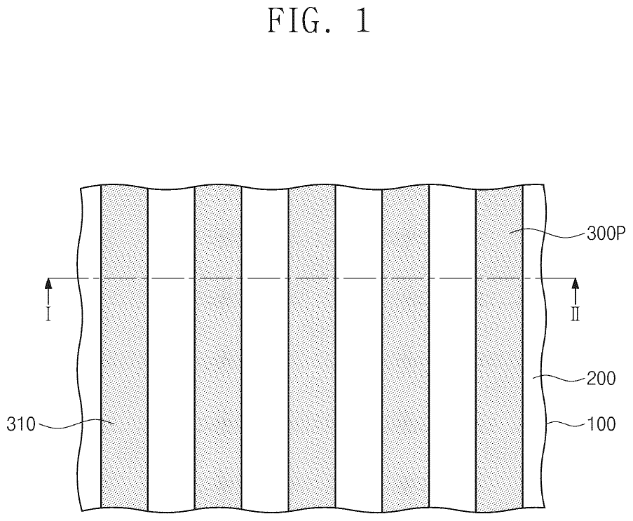

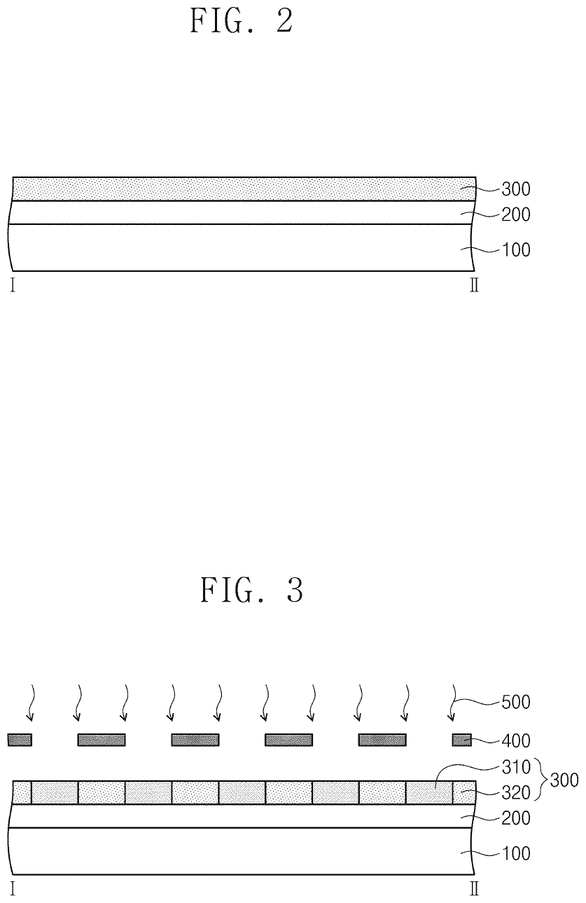

FIG. 1 is a plan view illustrating a resist pattern according to embodiments. FIGS. 2 to 5 are views for illustrating a method of forming a lower pattern according to embodiments, and correspond to cross-sectional views taken along line I-II of FIG. 1.

Referring to FIGS. 1 and 2, a substrate 100 may be prepared. A lower layer 200 and a resist layer 300 may be sequentially formed on the substrate 100. The lower layer 200 may be an etch target layer. The lower layer 200 may be formed of one selected from a semiconductor material, a conductive material, and an insulating material, or a combination thereof. The conductive material may include, but is not limited to, a metal such as aluminum, tungsten, or copper. The lower layer 200 may be formed as a single layer or may include a plurality of stacked layers. Although not shown, additional layers may be provided between the substrate 100 and the lower layer 200.

The resist layer 300 may be formed on the lower layer 200. The resist layer 300 may be a photoresist layer. Forming the resist layer 300 may be performed by a coating process using an organic resist material. For example, the resist layer 300 may include a chemically amplified resist material. The resist layer 300 may be hydrophobic.

As an example, a pre-bake process may be further performed on the resist layer 300. The pre-bake process may include heat treatment at a temperature of 70° C. to 300° C. for 10 to 300 seconds.

Referring to FIGS. 1 and 3, an exposure process of the resist layer 300 may be performed. For example, a light 500 may be irradiated onto the resist layer 300. Before the light 500 is irradiated, a photomask 400 may be disposed on the resist layer 300. The light 500 may be irradiated onto a first portion 310 of the resist layer 300 exposed by the photomask 400. Although FIG. 3 illustrates a photomask 400 where light 500 may transmit through the photomask 400, example embodiments are not limited thereto. In some embodiments, the photomask 400 may be reflective photomask.

The first portion 310 of the resist layer 300 may be an exposed portion. A chemical structure of the first portion 310 of the resist layer 300 exposed to the light 500 may be changed. A second portion 320 of the resist layer 300 may not be exposed to the light 500. The second portion 320 of the resist layer 300 may be an unexposed portion. A chemical structure of the second portion 320 of the resist layer 300 may not be changed. Accordingly, after the light 500 is irradiated, the first portion 310 of the resist layer 300 may have a different chemical structure from that of the second portion 320. The first portion 310 of the resist layer 300 may have different characteristics from the second portion 320. The first portion 310 and the second portion 320 of the resist layer 300 may be hydrophobic. However, the second portion 320 of the resist layer 300 may be more hydrophilic than the first portion 310.

The light 500 may be, for example, extreme ultraviolet (EUV). The extreme ultraviolet may have a wavelength of 13.0 nm to 13.9 nm, specifically, a wavelength of 13.4 nm to 13.6 nm. As another example, the light 500 may be an excimer laser, deep ultraviolet, ultraviolet, visible, electron, X-ray, g-line, h-line, and/or i-line. As another example, the light may include extreme ultraviolet (EUV), excimer laser, deep ultraviolet, ultraviolet, visible light, electron beam, X-ray, g-line, h-line, and/or i-line mixed light. For example, the excimer laser may have a wavelength of about 193 nm, and may be an ArF excimer laser. As another example, the excimer laser may have a wavelength of about 248 nm, and may be a KrF excimer laser. The g-line may have a wavelength of approximately 436 nm. The h-line may have a wavelength of about 405 nm. The i-line may have a wavelength of approximately 365 nm. The light 500 used in the exposure process may be irradiated under a condition of 0.1 mJ/cm², to 300 mJ/cm². For example, the light 500 may be irradiated under a condition of 0.1 mJ/cm², to 50 mJ/cm².

The exposure process may be performed by a contact exposure method, a proximity exposure method, or a projection exposure method. The exposure process may be performed using an exposure equipment such as an aligner, a stepper, and/or a scanner.

According to embodiments, a post-exposure bake (PEB) may be further performed on the resist layer 300. The post-exposure bake process may include heat treatment at a temperature of 70° C. to 300° C. for 10 to 300 seconds.

After the exposure process, the photomask 400 may be removed.

Referring to FIGS. 1, 3, and 4, a developing composition according to embodiments may be provided on the resist layer 300. Providing the developing composition may include spraying the developing composition. The spraying of the developing composition may be performed by a spray method. As another example, providing the developing composition may be performed by a dipping method.

The developing composition may include a developer and a copolymer. The developer may further include a solvent. The developer may be hydrophilic. When the developing composition does not include the copolymer, it may be difficult to apply the developer uniformly on the resist layer 300. According to embodiments, the copolymer may function as a surfactant. The developing composition may include the copolymer, and thus surface tension of the developing composition may be reduced, thereby improving wetting characteristics of the developing composition with respect to the resist layer 300. Accordingly, reactivity of the hydrophilic developer with respect to the first portion 310 of the hydrophobic resist layer 300 may be increased. The developer may react with the first portion 310 of the resist layer 300 to remove the first portion 310 of the resist layer 300.

The second portion 320 of the resist layer 300 may have a chemical structure different from that of the first portion 310, and may have low reactivity to a developer. For example, the developer may be hydrophilic, and the second portion 320 of the resist layer 300 may be hydrophobic. The second portion 320 of the resist layer 300 may be more hydrophobic than the first portion 310. The second portion 320 of the resist layer 300 may remain without being removed, to form a resist pattern 300P. The resist pattern 300P may be a photoresist pattern. The resist pattern 300P may be formed by a patterning process including the exposure process and the development process of the resist layer 300.

According to embodiments, the developing composition may include the copolymer, and thus reaction selectivity of the developer of the first portion 310 with respect to the second portion 320 of the resist layer 300 may be increased.

The developing composition may include the copolymer, and thus the developer may uniformly interact with the resist layer 300. For example, the developer may react uniformly with the first portion 310 of the resist layer 300. Accordingly, the resist pattern 300P may have uniform line-edge roughness (LER) characteristics and/or improved line width roughness (LWR) characteristics. Accordingly, patterning process margin and patterning process yield may be improved.

When a content ratio of the copolymer is too large or the content ratio of the solvent is too small, the resist pattern 300P may be damaged or have non-uniform roughness characteristics. When the content ratio of the copolymer is too small or the content ratio of the solvent is too large, the wetting characteristics of the developing composition with respect to the resist layer 300 may be reduced. Accordingly, it may be difficult to remove the first portion 310 of the resist layer 300. The resist pattern 300P may have poor roughness characteristics. According to embodiments, the copolymer may have 0.001 to 1 parts by weight, and the solvent may have 92 to 99.499 parts by weight, which may be based on a total weight of the developing composition. Accordingly, the line-edge roughness (LER) characteristics and the line width roughness (LWR) of the resist pattern 300P may be further improved.

The resist pattern 300P may be formed using the developing composition according to the embodiments, and thus defects in the resist pattern 300P during the development process may be limited and/or prevented. The defects of the resist pattern 300P may include an inclination of a sidewall of the resist pattern 300P with respect to a lower surface of the resist pattern 300P and a portion of the resist pattern 300P being undesirably removed. The defects of the resist pattern 300P may include formation of a pattern bridge. The resist pattern 300P may include portions spaced apart from each other, and the pattern bridge may include undesirably connected portions of the resist pattern 300P that are required to be spaced apart. According to embodiments, the resist pattern 300P may be formed using the developing composition, and the resist pattern 300P may be formed by desired development.

A cleaning process and a drying process may be further performed on the resist pattern 300P. According to embodiments, the developer may have a low surface tension, and thus pattern collapse of the resist pattern 300P may be limited and/or prevented in the cleaning process. The pattern collapse may mean that the second portion 320 of the developed resist layer 300 is collapsed due to the surface tension of the developing composition remaining while drying. The development process of the resist pattern 300P may be chemically stable.

Accordingly, the resist pattern 300P may be formed with a fine width “W” and a gap “D”. According to embodiments, the developing composition may further include a defoamer. In this case, generation of air bubbles in the development process may be limited and/or suppressed or reduced, and thus a side reaction between the resist pattern 300P and the air bubbles may be limited and/or prevented. Accordingly, the line-edge roughness (LER) characteristics and the line width roughness (LWR) of the resist pattern 300P may be further improved. A decrease in a thickness of the resist pattern 300P due to the air bubbles may be improved.

According to embodiments, the developing composition further includes the defoamer and a pH regulator, and thus defects in the resist pattern 300P may be further limited and/or prevented.

The resist pattern 300P may be a positive tone pattern.

As illustrated in FIG. 1, the resist pattern 300P may have a linear planar shape. For example, the resist pattern 300P may include portions extending in one direction. However, a planar shape of the resist pattern 300P may be variously modified, such as a zigzag shape, a honeycomb shape, or a circular shape. The resist pattern 300P may expose the lower layer 200.

Referring to FIGS. 1 and 5, the lower layer 200 exposed by the resist pattern 300P may be removed to form a lower pattern 200P. The lower layer 200 may be removed by an etching process. The lower layer 200 may have etch selectivity with respect to the resist pattern 300P. The lower pattern 200P may expose the substrate 100. As another example, the lower pattern 200P may expose another layer interposed between the substrate 100 and the lower pattern 200P. After that, the resist pattern 300P may be removed. Accordingly, the formation of the pattern may be completed. The pattern may refer to a lower pattern 200P. A width of the lower pattern 200P may correspond to the width “W” of the resist pattern 300P. The resist pattern 300P may have a narrow width “W”, and thus the lower pattern 200P may be formed with a narrow width. A spacing between the pattern portions of the lower pattern 200P may correspond to the gap “D” between the pattern portions of the resist pattern 300P.

According to embodiments, the lower pattern 200P may be a component of a semiconductor device. For example, the lower pattern 200P may be a semiconductor pattern, a conductive pattern, or an insulating pattern in a semiconductor device.

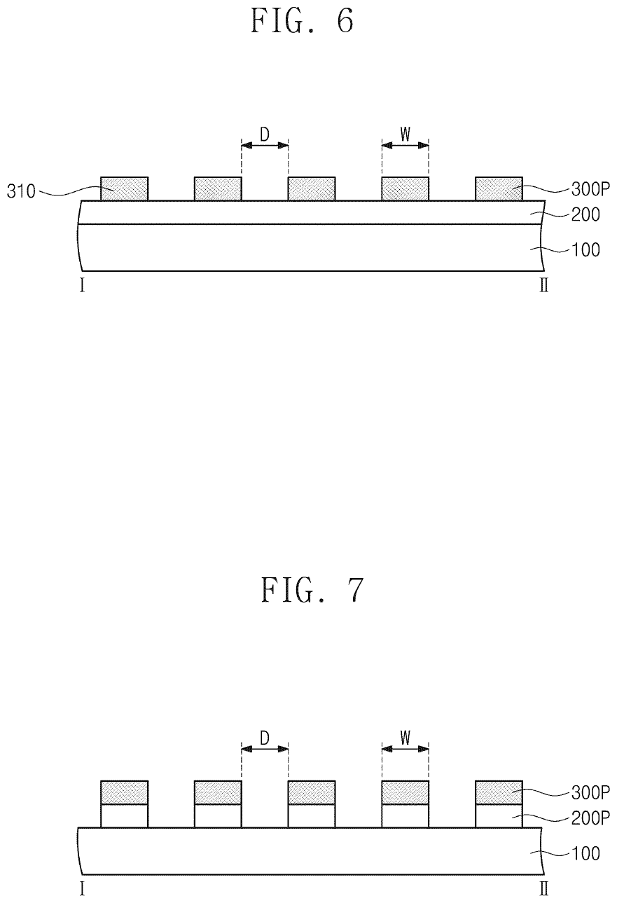

FIGS. 6 and 7 are views for illustrating a method of forming a lower pattern according to other embodiments, and correspond to cross-sectional views taken along line I-II of FIG. 1.

Referring to FIG. 6, a resist layer 300 and a lower layer 200 may be formed on a substrate 100. The substrate 100, the lower layer 200, and the resist layer 300 may be substantially the same as described above with reference to FIG. 2. An exposure process may be performed on the resist layer 300. The exposure process may be substantially the same as described with reference to FIG. 3. For example, after the exposure process is completed, a material of a first portion 310 of the resist layer 300 may have a different chemical structure from that of a second portion 320. However, the first portion 310 of the resist layer 300 may be more hydrophilic than the second portion 320.

Thereafter, a development process may be performed on the resist layer 300 to form a resist pattern 300P. The development process may be performed by substantially the same method as described with reference to FIG. 4. For example, the development process may be performed using the developing composition according to the embodiments. However, the developing composition according to the embodiments may have high reactivity with respect to the second portion 320 of the resist layer 300. As a result of the development process, the second portion 320 of the resist layer 300 may be removed by a developer. The developer may have low reactivity with respect to the first portion 310 of the resist layer 300. The first portion 310 of the resist layer 300 may remain without being removed to form a resist pattern 300P. The resist pattern 300P may be a negative tone pattern. The development process may be performed using the resist composition according to the embodiments, and thus the resist pattern 300P may have uniform line-edge roughness (LER) characteristics and/or improved line width roughness (LWR) characteristics.

Referring to FIG. 7, the lower layer 200 may be etched to form a lower pattern 200P. The etching of the lower layer 200 may be substantially the same as the method described with reference to FIG. 5. Thereafter, the resist pattern 300P may be removed.

Hereinafter, a preparation of a developing composition and a formation of the resist pattern will be described with reference to Experimental Examples of inventive concepts.

1. Preparation of Copolymer

### Copolymer Experimental Example 1: Preparation of Copolymer A

Vinylphosphonic acid (20 g) and monoethanolamine (22.6 g) were added in a reaction vessel with tetrahydrofuran (44.6 g) at a temperature of 10° C. and reacted for 8 hours. After completion of the reaction, a resulting salt was precipitated in hexane (200 g), filtered and dried to obtain phosphate A.

A mixture of tetrahydrofuran (10.00 g) and ethanol (2.00 g) at a temperature of 60° C. was added into the reaction vessel. Phosphate A (3.411 g) synthesized earlier, di(ethylene glycol) methyl ether methacrylate (8.367 g), and azobisisobutyronitrile (hereinafter, AIBN) (0.195 g) were added in the reaction vessel and reacted for 4 hours. After completion of the reaction, a solution was cooled to precipitate the polymer in hexane (150 g), and was filtered and dried. Thereby, copolymer A was obtained. A weight average molecular weight of the obtained copolymer A was measured using gel-permeation chromatography. The weight average molecular weight of copolymer A was 2010.

### Copolymer Experimental Example 2: Preparation of Copolymer B

Phosphate B was prepared in the same manner as in Copolymer Experimental Example 1, except that 2-methoxyethylamine (27.8 g) was added to tetrahydrofuran (47.8 g) instead of monoethanolamine.

Copolymer B was prepared in the same manner as in Experimental Example 1. However, phosphate B (3.411 g) was added instead of phosphate A, and di(ethylene glycol) methyl ether acrylate (6.903 g) was used instead of di(ethylene glycol) methyl ether methacrylate, and AIBN (0.174 g) was added. A weight average molecular weight of copolymer B was 2014.

### Copolymer Experimental Example 3: Preparation of Copolymer C

Phosphate C was prepared in the same manner as in Copolymer Experimental Example 1, except that diethanolamine (38.9 g) was added to tetrahydrofuran (58.9 g) instead of monoethanolamine.

Copolymer C was prepared in the same manner as in Experimental Example 1, except that phosphate C (3.411 g) was added instead of phosphate A, di(ethylene glycol) ethyl ether methacrylate (6.502 g) was added instead of di(ethylene glycol) methyl ether methacrylate, and AIBN (0.141 g) was added. A weight average molecular weight of copolymer C was 2035.

### Copolymer Experiment Example 4: Preparation of Copolymer D

Phosphate D was prepared in the same manner as in Copolymer Experimental Example 1 except that diisopropanolamine (49.3 g) was added to tetrahydrofuran (69.3) instead of monoethanolamine.

Copolymer D was prepared in the same manner as in Experimental Example 1, except that phosphate D (3.411 g) was added instead of phosphate A, and di(ethylene glycol) ethyl ether acrylate (5.144 g) was added instead of di(ethylene glycol) methyl ether methacrylate, and AIBN (0.120 g) was added. A weight average molecular weight of copolymer D was 2022.

### Copolymer Experimental Example 5: Preparation of Copolymer E

Phosphate E was prepared in the same manner as in Copolymer Experimental Example 1, except that triethylamine (37.5 g) was added to tetrahydrofuran (57.5 g) instead of monoethanolamine.

Copolymer E was prepared in the same manner as in Copolymer Experimental Example 1, except that phosphate E (3.411 g) was added instead of phosphate A, and tri(ethylene glycol) ethyl ether methacrylate (7.657 g) was added instead of di(ethylene glycol) methyl ether methacrylate, and AIBN (0.144 g) was added. A weight average molecular weight of copolymer E was 2019.

### Copolymer Experimental Example 6: Preparation of Copolymer F

Phosphate F was prepared in the same manner as in Copolymer Experimental Example 1, except that tributylamine (68.6 g) was added to tetrahydrofuran (88.6 g) instead of monoethanolamine.

Copolymer F was prepared in the same manner as in Copolymer Experimental Example 1, except that phosphate F (3.411 g) was added instead of phosphate A, and tri(ethylene glycol) ethyl ether acrylate (4.665 g) was added instead of di(ethylene glycol) methyl ether methacrylate, and AIBN (0.094 g) was added. A weight average molecular weight of copolymer F was 2032.

### Copolymer Experiment Example 7: Preparation of Copolymer G

Vinylsulfonic acid (20 g) and monoethanolamine (11.3 g) were added in a reaction vessel with tetrahydrofuran (31.3 g) and reacted for 8 hours while maintaining at a temperature of 10° C. After completion of the reaction, a resulting salt was precipitated in hexane (200 g), filtered and dried to prepare sulfonate A.

Sulfonate A (3.411 g) and 2-(2-hydroxyethoxy) synthesized previously in a reaction vessel in which tetrahydrofuran (10.00 g) and ethanol (2.00 g) were mixed at a temperature of 60° C. Ethyl methacrylate (10.536 g) and AIBN (0.265 g) were added and reacted for 4 hours. After completion of the reaction, a solution was cooled to precipitate a resulting polymer in hexane (150 g), and was filtered and dried to prepare copolymer G. A weight average molecular weight of copolymer G was 2022.

### Copolymer Experimental Example 8: Preparation of Copolymer H

Sulfonate B was prepared in the same manner as in Experimental Example 7 of the copolymer, except that 2-methoxyethylamine (13.9 g) was added to tetrahydrofuran (33.9 g) instead of monoethanolamine.

Copolymer H was prepared in the same manner as in Copolymer Experimental Example 7, except that sulfonate B (3.411 g) was added instead of sulfonate A, 2-(2-hydroxyethoxy)ethyl acrylate (8.946 g) was added instead of 2-(2-hydroxyethoxy)ethyl methacrylate), and AIBN (0.245 g) was added. A weight average molecular weight of copolymer H was 2017.

### Copolymer Experimental Example 9: Preparation of Copolymer I

Sulfonate C was prepared in the same manner as in Copolymer Experimental Example 7, except that diethanolamine (19.5 g) was added to tetrahydrofuran (39.5 g) instead of monoethanolamine.

Copolymer I was prepared in the same manner as in Copolymer Experimental Example 7, except that sulfonate C (3.411 g) was added instead of sulfonate A, di(ethylene glycol) methyl ether methacrylate (9.032 g) was added instead of 2-(2-hydroxyethoxy) ethyl methacrylate, AIBN (0.210 g) was added, and the reaction time was carried out for 2 hours. A weight average molecular weight of copolymer I was 1001.

### Copolymer Experimental Example 10: Preparation of Copolymer J

Sulfonate D was prepared in the same manner as in Experimental Example 7 of the copolymer, except that diisopropanolamine (24.7 g) was added to tetrahydrofuran (44.7 g) instead of monoethanolamine.

Copolymer J was prepared in the same manner as in Copolymer Experimental Example 7, except that sulfonate D (3.411 g) was added instead of sulfonate A, di(ethylene glycol) methyl ether acrylate (7.387 g) was added instead of 2-(2-hydroxyethoxy) ethyl methacrylate g), AIBN (0.186) was added, and the reaction time was carried out for 6 hours. A weight average molecular weight of copolymer J was 3037.

### Copolymer Experimental Example 11: Preparation of Copolymer K

Sulfonate E was prepared using the same method as in Experimental Example 7, except that triethylamine (18.7 g) was added to tetrahydrofuran (38.7 g) instead of monoethanolamine.

Copolymer K was prepared in the same manner as in Copolymer Experimental Example 7, except that sulfonate E (3.411 g) was added instead of sulfonate A, di(ethylene glycol) ethyl ether methacrylate (9.888 g) was added instead of 2-(2-hydroxyethoxy) ethyl methacrylate, AIBN (0.214 g) was added and the reaction time was carried out for 10 hours. A weight average molecular weight of copolymer K was 4011.

### Copolymer Experimental Example 12: Preparation of Copolymer L

Sulfonate L was prepared using the same method as in Experimental Example 7, except that tributylamine (34.3 g) was added to tetrahydrofuran (54.3 g) instead of monoethanolamine.

Copolymer K was prepared in the same manner as in Copolymer Experimental Example 7, except that sulfonate F (3.411 g) was added instead of sulfonate A, and di(ethylene glycol) ethyl ether acrylate (6.563 g) was added instead of 2-(2-hydroxyethoxy) ethyl methacrylate, AIBN (0.153 g) was added, and the reaction time was carried out for 2 hours. A weight average molecular weight of copolymer L was 1014.

### Copolymer Experimental Example 13: Preparation of Copolymer M

Phosphate A (3.411 g), tri(ethylene glycol) ethyl ether methacrylate (10.325 g), and AIBN (0.195 g) were added in a reaction vessel, in which tetrahydrofuran (10.00 g) and ethanol (2.00 g) were mixed, and were reacted at a temperature of 60° C. for 6 hours. After completion of the reaction, the solution was cooled. A resulting polymer in the solution was precipitated in hexane (150 g), and was filtered and dried to prepare a surfactant copolymer M. A weight average molecular weight of copolymer M was 3125.

### Copolymer Experimental Example 14: Preparation of Copolymer N

Copolymer N was prepared in the same manner as in Copolymer Experimental Example 13, except that sulfonate A (3.411 g) was added instead of phosphate A, and tri(ethylene glycol) ethyl ether acrylate (13.200 g) was added instead of tri(ethylene glycol) ethyl ether methacrylate, AIBN (0.265 g) was added, and the reaction time was carried out for 10 hours. A weight average molecular weight of copolymer N was 4110.

### Copolymer Experimental Example 15: Preparation of Copolymer O

Phosphate A (1.706 g), sulfonate A (1.254 g), 2-(2-hydroxyethoxy) ethyl methacrylate (3.872 g), and AIBN (0.122 g) were added in a reaction vessel in which tetrahydrofuran (10.00 g) and ethanol (2.00 g) were mixed and reacted at a temperature of 60° C. for 2 hours. After completion of the reaction, a solution was cooled. The polymer in the solution was precipitated in hexane (150 g), and was filtered and dried to prepare copolymer O. A weight average molecular weight of copolymer O was 1181.

### Copolymer Experimental Example 16: Preparation of Copolymer P

Copolymer P was prepared in the same manner as in Copolymer Experimental Example 15, except that phosphate D (1.706 g) was added instead of phosphate A, sulfonate D (1.099 g) was added instead of sulfonate A, 2-(2-hydroxyethoxy)ethyl acrylate (2.189 g) was added instead of 2-(2-hydroxyethoxy)ethyl methacrylate, AIBN (0.075 g) was added, and the reaction time was carried out for 6 hours. A weight average molecular weight of copolymer P was 3071.

### Copolymer Experimental Example 17: Preparation of Copolymer Q

Copolymer Q was prepared in the same manner as in Copolymer Experimental Example 15, except that phosphate E (1.706 g) was added instead of phosphate A, sulfonate E (1.150 g) was added instead of sulfonate A, di(ethylene glycol) methyl ether methacrylate (3.102 g) was added instead of 2-(2-hydroxyethoxy) ethyl methacrylate, AIBN (0.090 g) was added, and the reaction time proceeded to 10 hours. A weight average molecular weight of copolymer Q was 4007.

### Copolymer Experimental Example 18: Preparation of Copolymer R

Copolymer R was prepared in the same manner as in Copolymer Experimental Example 1, except that di(ethylene glycol) methyl ether acrylate (4.761 g) was added instead of di(ethylene glycol) methyl ether methacrylate, AIBN (0.120 g) was added, and the reaction time was 2 hours. A weight average molecular weight of copolymer R was 1107.

### Copolymer Experimental Example 19: Preparation of Copolymer S

Copolymer S was prepared in the same manner as in Copolymer Experimental Example 1, except that di(ethylene glycol) ethyl ether methacrylate (6.667 g) was added instead of di(ethylene glycol) methyl ether methacrylate, AIBN (0.144 g) was added, and the reaction time was 6 hours. A weight average molecular weight of copolymer S was 3025.

### Copolymer Experimental Example 20: Preparation of Copolymer T

Copolymer T was prepared in the same manner as in Copolymer Experimental Example 1, except that di(ethylene glycol) ethyl ether acrylate (8.367 g) was added instead of di(ethylene glycol) methyl ether methacrylate, AIBN (0.195 g) was added, and the reaction time was 10 hours. A weight average molecular weight of copolymer T was 4107.

Table 1 shows the first salts synthesized through the copolymer Experimental Examples 1 to 12.

TABLE 1

| Experimental | Sulfonic acid monomer/ | Amine compound | Prepared |
|---|---|---|---|
| Example | Phosphoric acid monomer | (Amine-based monomer) | first salt |
| 1 | vinyl phosphonic acid | monoethanolamine | Phosphate A |
| 2 | vinyl phosphonic acid | 2-Methoxyethylamine | Phosphate B |
| 3 | vinyl phosphonic acid | diethanolamine | Phosphate C |
| 4 | vinyl phosphonic acid | diisopropanolamine | Phosphate D |
| 5 | vinyl phosphonic acid | triethylamine | Phosphate E |
| 6 | vinyl phosphonic acid | tributylamine | Phosphate F |
| 7 | vinyl sulfonic acid | monoethanolamine | Sulfonate A |
| 8 | vinyl sulfonic acid | 2-Methoxyethylamine | Sulfonate B |
| 9 | vinyl sulfonic acid | diethanolamine | Sulfonate C |
| 10 | vinyl sulfonic acid | diisopropanolamine | Sulfonate D |
| 11 | vinyl sulfonic acid | triethylamine | Sulfonate E |
| 12 | vinyl sulfonic acid | tributylamine | Sulfonate F |

Table 2 shows the copolymers synthesized through the copolymer Experimental Examples 1 to 20.

TABLE 2

| Experimental | | | Synthesized |
|---|---|---|---|
| Example | First Salt | acrylate used | Copolymer |
| 1 | Phosphate A | di(ethylene glycol) methyl ether methacrylate | Copolymer A |
| 2 | Phosphate B | di(ethylene glycol) methyl ether acrylate | Copolymer B |
| 3 | Phosphate C | di(ethylene glycol) ethyl ether methacrylate | Copolymer C |
| 4 | Phosphate D | di(ethylene glycol) ethyl ether acrylate | Copolymer D |
| 5 | Phosphate E | tri(ethylene glycol) ethyl ether methacrylate | Copolymer E |
| 6 | Phosphate F | tri(ethylene glycol) ethyl ether acrylate | Copolymer F |
| 7 | Sulfonate A | 2-(2-hydroxyethoxy)ethyl methacrylate | Copolymer G |
| 8 | Sulfonate B | 2-(2-hydroxyethoxy)ethyl acrylate | Copolymer H |
| 9 | Sulfonate C | di(ethylene glycol) methyl ether methacrylate | Copolymer I |
| 10 | Sulfonate D | di(ethylene glycol) methyl ether acrylate | Copolymer J |
| 11 | Sulfonate E | di(ethylene glycol) ethyl ether methacrylate | Copolymer K |
| 12 | Sulfonate F | di(ethylene glycol) ethyl ether acrylate | Copolymer L |
| 13 | Phosphate A | tri(ethylene glycol) ethyl ether methacrylate | Copolymer M |
| 14 | Sulfonate A | tri(ethylene glycol) ethyl ether acrylate | Copolymer N |
| 15 | Phosphate A + | 2-(2-hydroxyethoxy)ethyl methacrylate | Copolymer O |
| | Sulfonate A | | |
| 16 | Phosphate D + | 2-(2-hydroxyethoxy)ethyl acrylate | Copolymer P |
| | Sulfonate D | | |
| 17 | Phosphate E + | di(ethylene glycol) methyl ether methacrylate | Copolymer Q |
| | Sulfonate E | | |
| 18 | Phosphate A | di(ethylene glycol) methyl ether acrylate | Copolymer R |
| 19 | Phosphate A | di(ethylene glycol) ethyl ether methacrylate | Copolymer S |
| 20 | Phosphate A | di(ethylene glycol) ethyl ether acrylate | Copolymer T |

2. Preparation of Developing Composition

### Comparative Example

As shown in Table 3, 2.38 g of tetraalkyl ammonium hydroxide (hereinafter, TMAH) was added to deionized water and stirred for 4 hours, and then passed through a nanofilter to obtain a developing composition.

TABLE 3

| | Added materials (constituent and content of developing Composition) | | | | | | |
|---|---|---|---|---|---|---|---|
| | | | | | pH regulator | | |
| | Copolymer type | | Defoamer material | | material and | | TMAH |
| | and content (g) | | and content (g) | | content (g) | | content (g) |
| Comparative | — | 0 | — | 0 | — | 0 | 2 |
| Example | | | | | | | |

### Experimental Examples

Using the copolymers prepared as shown in Table 2, the developing compositions were prepared as shown in Table 4 below. In detail, in the preparation of the developing compositions, deionized water was added as a remainder based on 100 g of the prepared developing composition, except for the copolymer, the defoamer, the pH regulator, and the TMAH developer. The added materials were stirred for 4 hours, and then passed through a nanofilter to obtain the developing compositions.

TABLE 4

| | Added materials (constituent and content of developing Composition) | | | | | | |
|---|---|---|---|---|---|---|---|
| | Copolymer | | Defoamer | | pH regulator | | |
| Experimental | type and | | material and | | material and | | TMAH |
| Example | content (g) | | content (g) | | content (g) | | content (g) |
| 1 | A | 0.05 | ethanol | 3 | triethylamine | 0.05 | 2 |
| 2 | B | 0.05 | isopropanol | 3 | hydroxylamine | 0.05 | 2 |
| 3 | C | 0.05 | n-butanol | 3 | triethylamine | 0.05 | 2 |
| 4 | D | 0.05 | 1-hexanol | 0.5 | hydroxylamine | 0.05 | 2 |
| 5 | E | 0.05 | 1-octanol | 0.03 | triethylamine | 0.05 | 2 |
| 6 | F | 0.05 | 1-Decanol | 0.003 | hydroxylamine | 0.05 | 2 |
| 7 | G | 0.05 | ethanol | 3 | tri-n-butylamine | 0.05 | 0.5 |
| 8 | H | 0.05 | isopropanol | 3 | monoethanolamine | 0.05 | 0.75 |
| 9 | I | 0.05 | n-butanol | 3 | tri-n-butylamine | 0.05 | 1 |
| 10 | J | 0.05 | 1-hexanol | 0.5 | monoethanolamine | 0.05 | 1.25 |
| 11 | K | 0.05 | 1-octanol | 0.03 | tri-n-butylamine | 0.05 | 1.5 |
| 12 | L | 0.05 | 1-Decanol | 0.003 | monoethanolamine | 0.05 | 1.75 |
| 13 | M | 0.05 | isopropanol | 3 | diethanolamine | 0.05 | 2 |
| 14 | N | 0.05 | isopropanol | 3 | diethanolamine | 0.05 | 0.5 |
| 15 | O | 0.05 | n-butanol | 3 | monoethanolamine | 0.05 | 0.75 |
| 16 | P | 0.05 | n-butanol | 3 | monoethanolamine | 0.05 | 1 |
| 17 | Q | 0.05 | n-butanol | 3 | monoethanolamine | 0.05 | 1.25 |
| 18 | R | 0.05 | ethanol | 3 | triethylamine | 0.05 | 1.5 |
| 19 | S | 0.05 | ethanol | 3 | triethylamine | 0.05 | 1.75 |
| 20 | T | 0.05 | ethanol | 3 | triethylamine | 0.05 | 2 |
| 21 | A | 0.01 | ethanol | 3 | triethylamine | 0.05 | 0.5 |
| 22 | B | 0.10 | isopropanol | 3 | hydroxylamine | 0.05 | 0.75 |
| 23 | C | 0.50 | n-butanol | 3 | triethylamine | 0.05 | 1 |
| 24 | D | 0.01 | 1-hexanol | 0.5 | hydroxylamine | 0.05 | 1.25 |
| 25 | E | 0.10 | 1-octanol | 0.03 | triethylamine | 0.05 | 1.5 |
| 26 | F | 0.50 | 1-Decanol | 0.003 | hydroxylamine | 0.05 | 1.75 |
| 27 | G | 0.01 | ethanol | 3 | tri-n-butylamine | 0.05 | 2 |
| 28 | H | 0.10 | isopropanol | 3 | monoethanolamine | 0.05 | 0.5 |
| 29 | I | 0.50 | n-butanol | 3 | tri-n-butylamine | 0.05 | 0.75 |
| 30 | J | 0.01 | 1-hexanol | 0.5 | monoethanolamine | 0.05 | 1 |
| 31 | K | 0.10 | 1-octanol | 0.03 | tri-n-butylamine | 0.05 | 1.25 |
| 32 | L | 0.50 | 1-Decanol | 0.003 | monoethanolamine | 0.05 | 1.5 |
| 33 | A | 0.05 | ethanol | 1 | triethylamine | 0.10 | 1.75 |
| 34 | B | 0.05 | isopropanol | 2 | hydroxylamine | 0.50 | 2 |
| 35 | C | 0.05 | n-butanol | 3 | triethylamine | 0.80 | 2 |
| 36 | D | 0.05 | 1-hexanol | 0.5 | hydroxylamine | 0.10 | 2 |
| 37 | E | 0.05 | 1-octanol | 0.03 | triethylamine | 0.50 | 2 |
| 38 | F | 0.05 | 1-Decanol | 0.003 | hydroxylamine | 0.80 | 2 |
| 39 | G | 0.05 | ethanol | 1 | tri-n-butylamine | 0.10 | 2 |
| 40 | H | 0.05 | isopropanol | 2 | monoethanolamine | 0.50 | 2 |
| 41 | I | 0.05 | n-butanol | 3 | tri-n-butylamine | 0.80 | 2 |
| 42 | J | 0.05 | 1-hexanol | 0.5 | monoethanolamine | 0.10 | 2.38 |
| 43 | K | 0.05 | 1-octanol | 0.03 | tri-n-butylamine | 0.50 | 2.38 |
| 44 | L | 0.05 | 1-Decanol | 0.003 | monoethanolamine | 0.80 | 2.38 |

3. Evaluation of Developing Composition

A contact angle and surface tension of the developing compositions are measured.

A general resist composition is coated on a silicon wafer substrate and a pre-bake process is performed on a hot plate at 110° C. for 60 seconds to form a coated resist layer. An exposure process is performed on the resist layer. Thereafter, a post-exposure bake (PEB) process is performed on the resist layer at 110° C. for 60 seconds. After spraying the developing compositions of Tables 3 and 4 on the resist layer for 20 seconds, respectively, a cleaning process and a spin drying process are performed to form a resist pattern.

CD-SEM of the resist pattern is measured. From measured CD-SEM results, sensitivity (Eop) forming target critical dimension (hereinafter, CD) line & space, line width roughness (LWR), local CD uniformity (LCU), in-wafer uniformity (IWU) and pattern defects are evaluated.

Table 5 shows the results of evaluation of surface tension, contact angle, sensitivity (Eop), line width roughness (LWR) of resist pattern, local CD uniformity (LCDU), in-wafer uniformity (IWU) and pattern defects of the developing compositions. In Table 5, LCDU is an average value of a deviation of CD size for a local area, and IWU is an average value of a deviation of the CD size in the silicon wafer substrate. The pattern defect is a result of evaluating occurrence of a pattern bridge.

TABLE 5

| | surface | | | | | | |
|---|---|---|---|---|---|---|---|
| Developing | tension | Contact | Eₒₚ | LWR | LCDU | IWU | Pattern |
| composition | (dyne/cm) | angle(°) | (mJ/cm²) | (nm) | (nm) | (nm) | defect |
| Experimental | 58.5 | 64.47 | 27.88 | 1.56 | 1.19 | 0.76 | ● |
| Example 1 | | | | | | | |
| Experimental | 56.7 | 64.03 | 27.60 | 1.57 | 1.18 | 0.76 | ● |
| Example 2 | | | | | | | |
| Experimental | 55.8 | 63.40 | 27.32 | 1.58 | 1.18 | 0.75 | ◯ |
| Example 3 | | | | | | | |
| Experimental | 54.3 | 61.13 | 27.04 | 1.59 | 1.17 | 0.74 | ◯ |
| Example 4 | | | | | | | |
| Experimental | 53.6 | 58.58 | 26.20 | 1.60 | 1.17 | 0.74 | ◯ |
| Example 5 | | | | | | | |
| Experimental | 52.2 | 56.10 | 25.92 | 1.66 | 1.16 | 0.73 | ⊚ |
| Example 6 | | | | | | | |
| Experimental | 60.2 | 65.67 | 30.68 | 1.49 | 1.17 | 0.76 | ▴ |
| Example 7 | | | | | | | |
| Experimental | 57.3 | 65.11 | 30.12 | 1.52 | 1.17 | 0.77 | ▴ |
| Example 8 | | | | | | | |
| Experimental | 56.1 | 64.59 | 29.56 | 1.54 | 1.16 | 0.77 | Δ |
| Example 9 | | | | | | | |
| Experimental | 55.9 | 62.54 | 28.72 | 1.56 | 1.17 | 0.75 | Δ |
| Example 10 | | | | | | | |
| Experimental | 55.1 | 59.17 | 27.04 | 1.58 | 1.17 | 0.74 | ● |
| Example 11 | | | | | | | |
| Experimental | 53.4 | 57.28 | 27.04 | 1.59 | 1.17 | 0.75 | ◯ |
| Example 12 | | | | | | | |
| Experimental | 56.3 | 62.27 | 27.04 | 1.60 | 1.19 | 0.76 | ◯ |
| Example 13 | | | | | | | |
| Experimental | 55.8 | 60.85 | 28.44 | 1.52 | 1.15 | 0.76 | ▴ |
| Example 14 | | | | | | | |
| Experimental | 58.1 | 62.51 | 28.16 | 1.53 | 1.14 | 0.76 | ▴ |
| Example 15 | | | | | | | |
| Experimental | 57.8 | 62.13 | 27.88 | 1.53 | 1.15 | 0.75 | Δ |
| Example 16 | | | | | | | |
| Experimental | 57.1 | 61.67 | 28.16 | 1.55 | 1.16 | 0.75 | Δ |
| Example 17 | | | | | | | |
| Experimental | 58.9 | 66.00 | 28.44 | 1.54 | 1.18 | 0.74 | ● |
| Example 18 | | | | | | | |
| Experimental | 57.8 | 64.61 | 28.16 | 1.55 | 1.19 | 0.75 | ◯ |
| Example 19 | | | | | | | |
| Experimental | 57.1 | 62.44 | 27.04 | 1.58 | 1.19 | 0.76 | ◯ |
| Example 20 | | | | | | | |
| Experimental | 62.9 | 68.61 | 31.24 | 1.53 | 1.13 | 0.74 | ▴ |
| Example 21 | | | | | | | |
| Experimental | 51.2 | 58.59 | 28.16 | 1.56 | 1.17 | 0.77 | ▴ |
| Example 22 | | | | | | | |
| Experimental | 43.7 | 54.97 | 26.48 | 1.57 | 1.17 | 0.76 | Δ |
| Example 23 | | | | | | | |
| Experimental | 57.6 | 63.75 | 28.44 | 1.54 | 1.14 | 0.72 | ▴ |
| Example 24 | | | | | | | |
| Experimental | 48.2 | 53.98 | 25.92 | 1.63 | 1.18 | 0.75 | ● |
| Example 25 | | | | | | | |
| Experimental | 42.3 | 48.41 | 24.80 | 1.65 | 1.17 | 0.77 | ◯ |
| Example 26 | | | | | | | |
| Experimental | 63.5 | 69.32 | 27.60 | 1.59 | 1.19 | 0.74 | ● |
| Example 27 | | | | | | | |
| Experimental | 53.6 | 63.15 | 30.12 | 1.57 | 1.15 | 0.76 | ▴ |
| Example 28 | | | | | | | |
| Experimental | 47.4 | 54.73 | 27.04 | 1.56 | 1.15 | 0.77 | Δ |
| Example 29 | | | | | | | |
| Experimental | 56.6 | 65.03 | 28.72 | 1.58 | 1.17 | 0.73 | ▴ |
| Example 30 | | | | | | | |
| Experimental | 49.9 | 54.12 | 26.20 | 1.59 | 1.17 | 0.75 | ● |
| Example 31 | | | | | | | |
| Experimental | 41.4 | 46.43 | 24.80 | 1.67 | 1.18 | 0.77 | ◯ |
| Example 32 | | | | | | | |
| Experimental | 61.4 | 66.10 | 27.88 | 1.55 | 1.19 | 0.74 | Δ |
| Example 33 | | | | | | | |
| Experimental | 55.1 | 65.67 | 27.32 | 1.56 | 1.18 | 0.75 | ● |
| Example 34 | | | | | | | |
| Experimental | 53.3 | 62.77 | 26.76 | 1.59 | 1.16 | 0.76 | ⊚ |
| Example 35 | | | | | | | |
| Experimental | 51.5 | 60.43 | 26.48 | 1.58 | 1.18 | 0.74 | ● |
| Example 36 | | | | | | | |
| Experimental | 46.8 | 57.07 | 26.48 | 1.57 | 1.17 | 0.74 | ◯ |
| Example 37 | | | | | | | |
| Experimental | 42.9 | 54.70 | 25.64 | 1.62 | 1.15 | 0.75 | ⊚ |
| Example 38 | | | | | | | |
| Experimental | 62.4 | 67.00 | 27.88 | 1.57 | 1.17 | 0.77 | ● |
| Example 39 | | | | | | | |
| Experimental | 57.1 | 65.98 | 27.60 | 1.58 | 1.18 | 0.75 | ◯ |
| Example 40 | | | | | | | |
| Experimental | 55.4 | 63.96 | 26.76 | 1.59 | 1.18 | 0.75 | ⊚ |
| Example 41 | | | | | | | |
| Experimental | 53.1 | 61.63 | 26.20 | 1.61 | 1.19 | 0.76 | ◯ |
| Example 42 | | | | | | | |
| Experimental | 53.6 | 57.66 | 25.64 | 1.63 | 1.18 | 0.77 | ⊚ |
| Example 43 | | | | | | | |
| Experimental | 52.8 | 55.27 | 24.80 | 1.66 | 1.18 | 0.80 | ⊚ |
| Example 44 | | | | | | | |
| comparative | 72.8 | 77.62 | 28.16 | 1.64 | 1.25 | 0.82 | Reference |
| example | | | | | | | |

Pattern defect: pattern bridge: evaluated by the numerical value of the experimental example compared to the numerical value of the comparative example
⊚: 80% or more improvement
◯: 60~80% improvement
●: 40~60% improvement
Δ: 20~40% improvement
▴: 0~20% improvement

Referring to Tables 3 to 5, each of the developing compositions of Experimental Examples 1 to 44 may include a copolymer. The developing composition of the Comparative Example does not include a copolymer. Experimental Examples 1 to 44 have a lower surface tension and a lower contact angle than those of Comparative Example. The developing compositions of Experimental Example 21, Experimental Example 25, Experimental Example 28, and Experimental Example 31 may contain 0.10 parts by weight of the copolymer. As the content of the copolymer increases, the contact angle of the developing composition may decrease.

Resist patterns prepared by using the developing compositions of Experimental Examples 1 to 44 may have a reduced Eop value than that of the developing composition of Comparative Example. The resist patterns prepared by using the developing compositions of Experimental Examples 1 to 43 showed a lower pattern surface roughness value than that of the developing composition of Comparative Example. The resist patterns prepared by using the developing compositions of Experimental Examples 1 to 44 have improved local CD uniformity (LCDU), improved silicon wafer substrate CD uniformity (IWU), and improved pattern defects characteristics compared to the developing composition of Comparative Example.

According to embodiments, the developing composition may include the copolymer, and thus the resist pattern prepared by using the developing composition may be well formed. For example, the resist pattern may have improved Eop values, improved linewidth roughness (LWR) characteristics, improved local CD uniformity (LCDU) characteristics, improved intra-wafer uniformity (IWU) characteristics, and improved pattern defect (i.e., bridge) characteristics.

According to inventive concepts, the developing composition has the low surface tension, thereby improving the wetting characteristics for the resist layer. The resist pattern manufactured using the developing composition according to the embodiments may have the improved pattern uniformity, the fine pitch, and the improved defect characteristics.

While embodiments are described above, a person skilled in the art may understand that many modifications and variations are made without departing from the spirit and scope of inventive concepts defined in the following claims.

Accordingly, example embodiments of inventive concepts should be considered in all respects as illustrative and not restrictive, with the spirit and scope of inventive concepts being indicated by the appended claims.

What is claimed is:

1. A developing composition comprising:
a first repeating unit represented by Chemical Formula A1, a second repeating unit represented by Chemical Formula A2, or both the first repeating unit represented by Chemical Formula A1 and the second repeating unit represented by Chemical Formula A2; and
a copolymer including a third repeating unit represented by Chemical Formula A3, 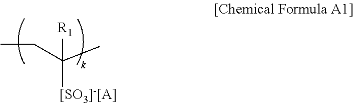
wherein, in Chemical Formula A1,
R₁ is one of hydrogen, an alkyl group having 1 to 3 carbon atoms, and a halogenated alkyl group having 1 to 3 carbon atoms,
A is a substituted or unsubstituted ammonium salt, and
k is an integer selected from 1 to 5000. 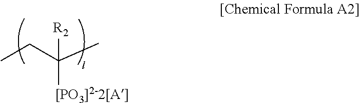
wherein, in Chemical Formula A2,
R₂ is one of hydrogen, an alkyl group having 1 to 3 carbon atoms, and a halogenated alkyl group having 1 to 3 carbon atoms,
A′ is a substituted or unsubstituted ammonium salt, and
l is an integer selected from 1 to 5000, 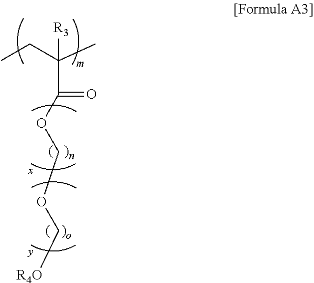
wherein, in Chemical Formula A3,
R₃ is one of hydrogen, an alkyl group having 1 to 3 carbon atoms, and a halogenated alkyl group having 1 to 3 carbon atoms,
R₄ is hydrogen, an alkyl group having 1 to 10 carbon atoms, or a hydroxyalkyl group having 1 to 10 carbon atoms,
m is an integer selected from 1 to 5000,
x is an integer selected from 1 to 100,
y is an integer selected from 0 to 100,
n is an integer selected from 1 to 5, and
o is an integer selected from 1 to 5.

2. The developing composition claim 1, wherein,
in Chemical Formula A1, A includes a material represented by Chemical Formula 2, 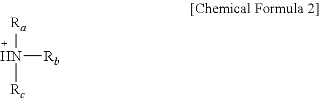
in Chemical Formula 2, each of Rₐ, R_{b}, and R_{c} is independently hydrogen, a hydroxyl group, an alkoxy group having 1 to 10 carbon atoms, an alkyl group having 1 to 10 carbon atoms, an alkoxy alkyl group having 2 to 10 carbon atoms, a hydroxyalkyl group having 1 to 10 carbon atoms, or a substituted or unsubstituted aryl group having 6 to 12 carbon atoms.

3. The developing composition of claim 2, wherein, in Chemical Formula 2, at least one of Rₐ, R_{b}, and R_{c} includes a hydroxyalkyl group.

4. The developing composition of claim 1, wherein in Chemical Formula A2, A′ includes a material represented by Chemical Formula 3. 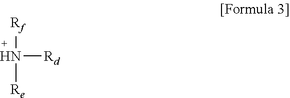
in Chemical Formula 3, each of R_{d}, Rₑ, and R_{f} is independently hydrogen, a hydroxyl group, an alkoxy group having 1 to 10 carbon atoms, an alkyl group having 1 to 10 carbon atoms, an alkoxy alkyl group having 2 to 10 carbon atoms, a hydroxyalkyl group having 1 to 10 carbon atoms, or a substituted or unsubstituted aryl group having 6 to 12 carbon atoms.

5. The developing composition of claim 1, wherein the copolymer includes the first repeating unit.

6. The developing composition of claim 1, wherein the copolymer includes the second repeating unit.

7. The developing composition of claim 1, further comprising a developer,
wherein the developer includes a tetraalkyl ammonium hydroxide having 4 to 20 carbon atoms.

8. The developing composition of claim 1, further comprising:
a defoamer,
wherein the defoamer includes an aliphatic alkyl alcohol compound having 1 to 10 carbon atoms and a cyclic aliphatic alkyl alcohol compound having 1 to 10 carbon atoms.

9. The developing composition of claim 1, further comprising:
a pH regulator.

10. The developing composition of claim 9, wherein the pH regulator includes a hydroxyl amine or an alkyl amine having 1 to 15 carbon atoms.

11. A developing composition comprising:
a developer; and
a copolymer represented by Chemical Formula 1, 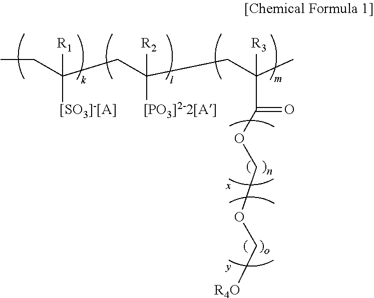
wherein, in Chemical Formula 1,
each of R₁, R₂, and R₃ is independently one of hydrogen, an alkyl group having 1 to 3 carbon atoms, and a halogenated alkyl group having 1 to 3 carbon atoms,
R₄ is hydrogen, an alkyl group having 1 to 10 carbon atoms, or a hydroxyalkyl group having 1 to 10 carbon atoms,
each of A and A′ is independently a substituted or unsubstituted ammonium salt,
x is an integer selected from 1 to 100,
y is an integer selected from 0 to 100,
n is an integer selected from 1 to 5,
o is an integer selected from 1 to 5,
k, l, and m are each mole fraction of repeating units,
each of k and l is independently 0 to 0.3, k+l is 0.05 to 0.3, m is 0.7 to 0.95, and k+l+m is 1.

12. The developing composition of claim 11, wherein,
in Chemical Formula 1, A includes a material represented by Chemical Formula 2, and A′ includes a material represented by Chemical Formula 3, 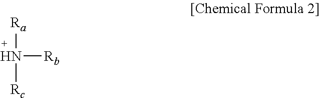
in Chemical Formula 2, each of Rₐ, R_{b}, and R_{c} is independently hydrogen, a hydroxyl group, an alkoxy group having 1 to 10 carbon atoms, an alkyl group having 1 to 10 carbon atoms, an alkoxy alkyl group having 2 to 10 carbon atoms, a hydroxyalkyl group having 1 to 10 carbon atoms, or a substituted or unsubstituted aryl group having 6 to 12 carbon atoms, 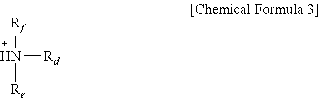
in Chemical Formula 3, each of R_{d}, Rₑ, and R_{f} is independently hydrogen, a hydroxyl group, an alkoxy group having 1 to 10 carbon atoms, an alkyl group having 1 to 10 carbon atoms, an alkoxy alkyl group having 2 to 10 carbon atoms, a hydroxyalkyl group having 1 to 10 carbon atoms, or a substituted or unsubstituted aryl group having 6 to 12 carbon atoms.

13. The developing composition of claim 11, wherein
based on a total weight of the developing composition,
the developer is 0.5 to 3 parts by weight, and
the copolymer is 0.001 to 1 part by weight.

14. The developing composition of claim 13, further comprising:
0.001 to 3 parts by weight of a defoamer, based on the total weight of the developing composition.

15. The developing composition of claim 13, further comprising:
0.001 to 3 parts by weight of a pH regulator, based on the total weight of the developing composition.

16. The developing composition of claim 11, further comprising:
a defoamer including an alkyl alcohol compound having 1 to 10 carbon atoms; and
a pH regulator including a hydroxyl amine or an alkyl amine having 1 to 15 carbon atoms,
wherein the developer includes at least one of tetramethyl ammonium hydroxide (TMAH), ethyltrimethylammonium hydroxide (ETMAH), tetraethylammonium hydroxide (TEAH), tetrapropylammonium hydroxide (TPAH), or tetrabutylammonium hydroxide (TBAH).

17. The developing composition of claim 11, wherein the copolymer has a weight average molecular weight (Mw) of 300 g/mol to 50,000 g/mol.

18. A method of forming a pattern comprising:
forming a resist layer on a substrate;
performing an exposure process of irradiating light onto the resist layer; and
performing a development process using the developing composition according to claim 1 on the resist layer.

19. The method of forming the pattern of claim 18, wherein the performing the exposure process includes irradiating extreme ultraviolet (EUV) light during the irradiating light onto the resist layer.

20. The method of forming the pattern of claim 18, wherein
the resist layer is hydrophobic, and
in the performing the development process, the developing composition further includes an aqueous alkali-based developer.
